(19) United States
(12) Patent Application Publication
(10) Pub. No.: US 2009/0042377 A1
(43) Pub. Date: Feb. 12, 2009

(54) METHOD FOR FORMING SELF-ALIGNED WELLS TO SUPPORT TIGHT SPACING

(76) Inventor: Seetharaman Sridhar, Richardson, TX (US)

Correspondence Address: TEXAS INSTRUMENTS INCORPORATED, P O BOX 655474, M/S 3999, DALLAS, TX, 75265, US

(21) Appl. No.: 11/835,762

(22) Filed: Aug. 8, 2007

(51) Int. Cl. H01L 21/425

(52) U.S. Cl. 438/527; 257/E21.474

(57) ABSTRACT

Methods include utilizing a single mask layer to form tightly spaced, adjacent first-type and second-type well regions. The mask layer is formed over a substrate in a region in which the second-type well regions will be formed. The first-type well regions are formed in the exposed portions of the substrate. Then, the second-type well-regions are formed through the resist mask.

### FIELD

This invention relates generally to semiconductor fabrication.

### BACKGROUND

Currently, in semiconductor fabrication, N-type and P-type well regions are formed in a substrate by utilizing a dual masking process. FIGS. 1A and 1B illustrate a convention process for forming N-type and P-type well regions by utilizing a dual masking process.

As illustrated in FIG. 1A, a device 100 includes a substrate 102 and an isolation feature 104. A resist mask 106 is formed over a portion of the substrate were a P-well region will be formed. Then, an ion implantation 108 is performed to form N-well region 110. Subsequently, as illustrated in FIG. 1B resist mask 106 is removed and a second resist mask 112 is formed over N-well region 110. Then, an ion implantation 114 is performed to form P-well region 112.

As illustrated in FIG. 1B, a misalignment 116 is formed between N-well region 110 and P-well region 116. The misalignment is due to the use of two separate resist masks. In the conventional process, the second resist must be formed with precession in order to align the edge of the resist mask with the boundary of the formed N-well region. However, under the conventional method of forming the mask, difficulty can arise in aligning the resist mask with the boundary of the N-well. If the resist mask is misaligned, the P-well region and N-well region will be misaligned and tightly spaced P-well and N-well will not occur. As a result, the performance of the semiconductor device can be affected. As such, processes are needed which allow N-well regions and P-well regions to be formed that are tightly spaced with minimum added process steps.

### SUMMARY OF THE INVENTION

An embodiment of the present disclosure is directed to a method of fabricating a semiconductor device. The method includes forming a mask layer over a portion of a substrate; implanting ions in the substrate to form a first-type well region in an un-masked portion of the substrate; and implanting ions in the substrate to form a second-type well region under the mask layer. The ions are implanted at an energy to form the second-type well region through the mask layer.

Another embodiment is directed to a method of fabricating a semiconductor device. The method includes forming a mask layer over a portion of a substrate; implanting ions in the substrate to form a plurality of first-type well regions in an un-masked portion of the substrate; and implanting ions in the substrate to form a plurality of second-type well regions under the mask layer. The ions are implanted at an energy to form the plurality of second-type well regions through the mask layer.

Additional embodiments of the disclosure will be set forth in part in the description which follows, and in part will be obvious from the description, or may be learned by practice of the present disclosure. The embodiments of the disclosure will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the disclosure and together with the description, serve to explain the principles of the embodiments.

FIG. 1 is a diagram illustrating a conventional method for forming well regions.

FIG. 2 is a flow diagram illustrating a method for forming first-type and second-type well regions consistent with embodiments of the present disclosure.

FIGS. 3A-3D are diagrams illustrating a method for forming N-type and P-type well regions consistent with embodiments of the present disclosure.

FIG. 4 is a diagram illustrating a method for forming multiple N-type and P-type well regions consistent with embodiments of the present disclosure.

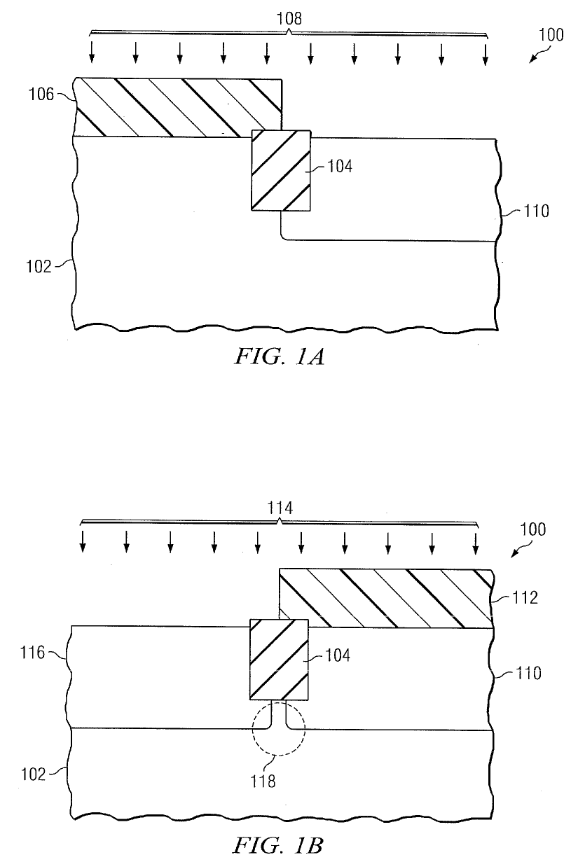

### DESCRIPTION OF THE EMBODIMENTS

Embodiments of the present disclosure are directed to methods for forming self-aligned and tightly spaced well regions. The methods include utilizing a single mask layer to form tightly spaced, adjacent first-type and second-type well regions. The mask layer is formed over a substrate in a region in which the second-type well regions will be formed. The first-type well regions are formed in the exposed portions of the substrate. Then, the second-type well-regions are formed through the resist mask.

By utilizing a single mask layer, a second mask layer, which must align with the formed first-type well regions, is not required. As such, self-aligned and tightly spaced well regions can be formed.

Reference will now be made in detail to the exemplary embodiments of the present disclosure, an example of which is illustrated in the accompanying drawings. Wherever possible, the same reference numbers will be used throughout the drawings to refer to the same or like parts.

In the following description, reference is made to the accompanying drawings that form a part thereof, and in which is shown by way of illustration specific exemplary embodiments which may be practiced. These embodiments are described in sufficient detail to enable those skilled in the art to practice the embodiments and it is to be understood that other embodiments may be utilized and that changes may be made without departing from the scope of the invention. The following description is, therefore, merely exemplary.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

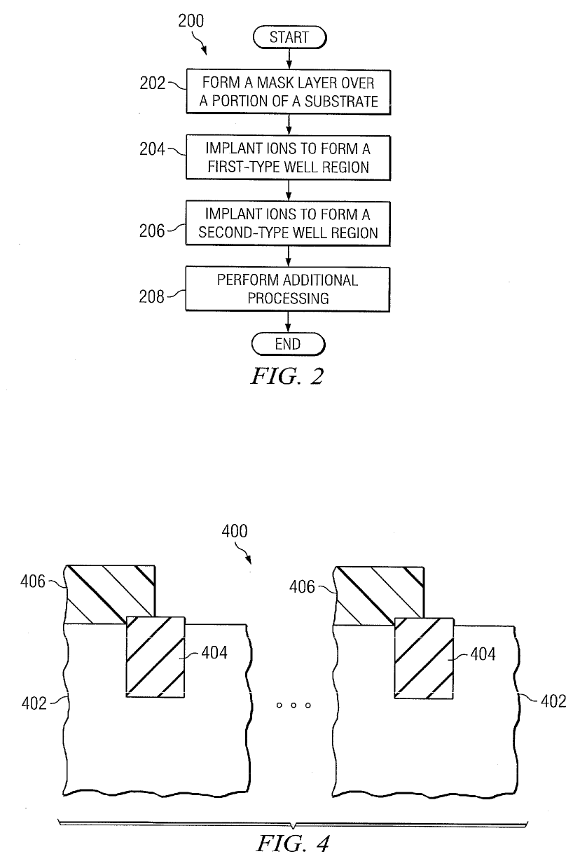

FIG. 2 is a flow diagram illustrating a method 200 for forming adjacent self-aligned and tightly spaced well regions. According to embodiments of the present disclosure, the well regions are formed by utilizing single mask layer during dopant implantation for both a first-type and second-type well regions.

Method 200 begins by forming a mask layer over a substrate (stage 202). The mask layer is formed so that a portion of the substrate is exposed and an adjacent portion of the substrate is covered. The exposed portion will be the location of a first-type well region and the covered portion will be the location of the second-type well region.

For example, the first-type well region may be an N-type well region and the second-type well region may be a P-type well region. One skilled in the art will realize that the first-type and second-type well regions may be N-type or P-type regions or vice versa.

The substrate can be formed from any suitable semiconductor material, such as silicon. Additionally, the substrate can include other semiconductor device features such as an isolation feature.

After forming the mask layer, ions are implanted to form the first-type well region (stage 204). For example, if the first-type well region is an N-type well region, arsenic, phosphorous, antimony, or other suitable n-type dopants can be implanted in the substrate during ion implantation to form the N-type well region.

The ion implantation can use a suitable energy, concentration, and implantation time to form the first-type well region in the substrate. For example, if the first type well-region is an N-type well region, one or more implantations of Phosphorus (P) can be performed with the implants ranging from approximately 1e12 atoms/cm² to approximately 1e14 atoms/cm² at implantation energies ranging from approximately 20 KeV to approximately 700 KeV. For example, multiple P implants can be approximately 1e12 atoms/cm² at an implantation energy of approximately 50 KeV, approximately 4e12 atoms/cm² at an implantation energy of approximately 150 KeV, approximately 4e12 atoms/cm² at an implantation energy of approximately 320 KeV, and approximately 4e13 atoms/cm² at an implantation energy of approximately 675 KeV.

After forming the first-type well region, ions are implanted to form the second-type well region (stage 206). The ion implantation is performed such that the well region is formed through the mask layer. For example, if the second-type well region is a P-type well region, Boron (B), indium (In) or other suitable P-type dopants can be implanted in the substrate during ion implantation to form the P-type well region.

The ion implantation can use a suitable energy, concentration, and implantation time to form the second-type well region through the mask layer in the substrate. For example, if the second-type well region is a P-type well region one or more implantations of B can be performed with the implants ranging from approximately 1e12 atoms/cm² to approximately 1e14 atoms/cm² at implantation energies ranging from approximately 500 KeV to approximately 1500 KeV. For example, multiple B implants can be approximately 8e12 atoms/cm² at an implantation energy of approximately 550 KeV, approximately 3.5e13 atoms/cm² at an implantation energy of approximately 1000 KeV, approximately 2e12 atoms/cm² at an implantation energy of approximately 20 KeV, and approximately 7e12 atoms/cm² at an implantation energy of approximately 70 KeV.

Since only a single mask layer is utilized, a second-type semiconductor region will be formed below the first-type well region. Since ion implantation utilizes energies suitable to form the second-type well region through the mask layer, the second-type region is formed below the first-type well region at a depth such that the second-type region does not affect the performance of the well regions. Additionally, since only a single mask layer is utilized during both ion implantations, the first-type and second-type well regions are self-aligned and tightly spaced.

As described above, the second-type well region can be formed utilizing both deep and shallow implants with the single mask layer. Alternatively, the mask layer can be utilized with high energy implants to form the deep implants, and a separate mask can be utilized with low energy implants to from shallow implants.

In this example, high energy ions are implanted to form the deep regions of the second-type well region. Then, the mask layer can be removed. Then, a separate mask layer can be formed over the first-type well region. The separate mask layer is formed so that the second-type well region is exposed and the first-type well region is covered.

After forming the separate mask layer, low energy ions are implanted to form the shallow regions of the second-type well region. For example, if the second-type well region is a P-type well region, two implantations of B can be performed with the implants of approximately 2e12 atoms/cm² at an implantation energy of approximately 20 KeV and approximately 7e12 atoms/cm² at an implantation energy of approximately 70 KeV.

Since only a single mask layer is utilized during the deep implants, a second-type semiconductor region will be formed below the first-type well region. Since ion implantation utilizes energies suitable to form deep implants of the second-type well region through the mask layer, the second-type region is formed below the first-type well region at a depth such that the second-type region does not affect the performance of the well regions. Additionally, since only a single mask layer is utilized during both ion implantation of the first type well region and the deep implants of the second-type well region, the first-type and second-type well regions are self-aligned and tightly spaced.

Subsequently, the mask layer can be removed and additional semiconductor processing can be performed (stage 208). For example, processing can be performed to fabricate a first-type semiconductor device and a second type semiconductor device in the second-type well region and first-type well region, respectively.

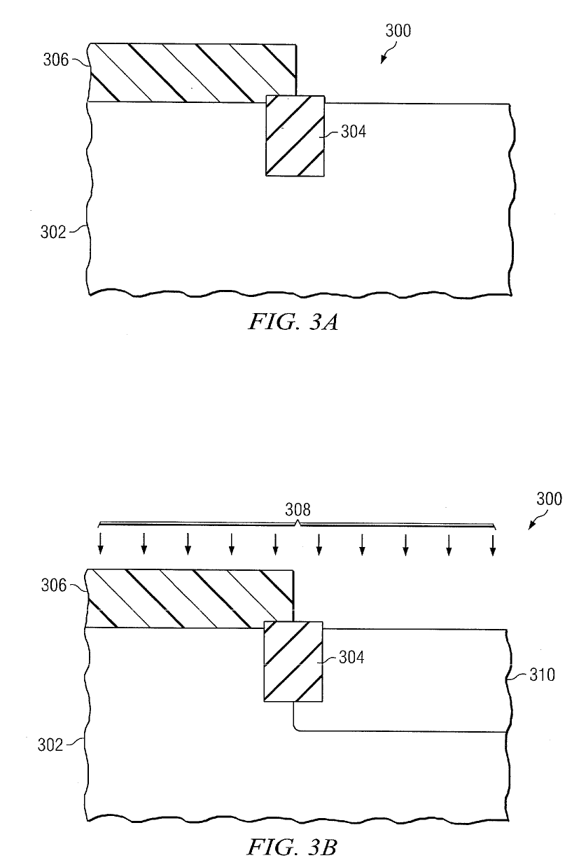

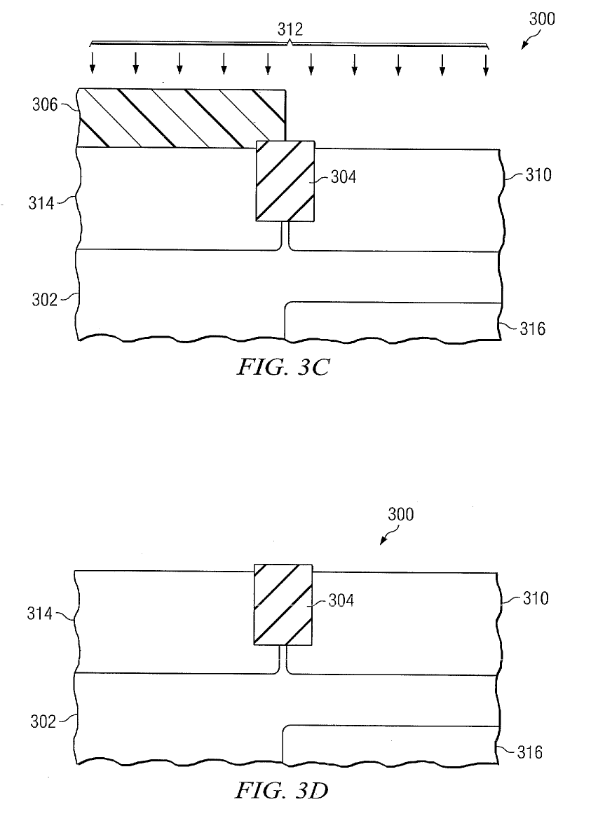

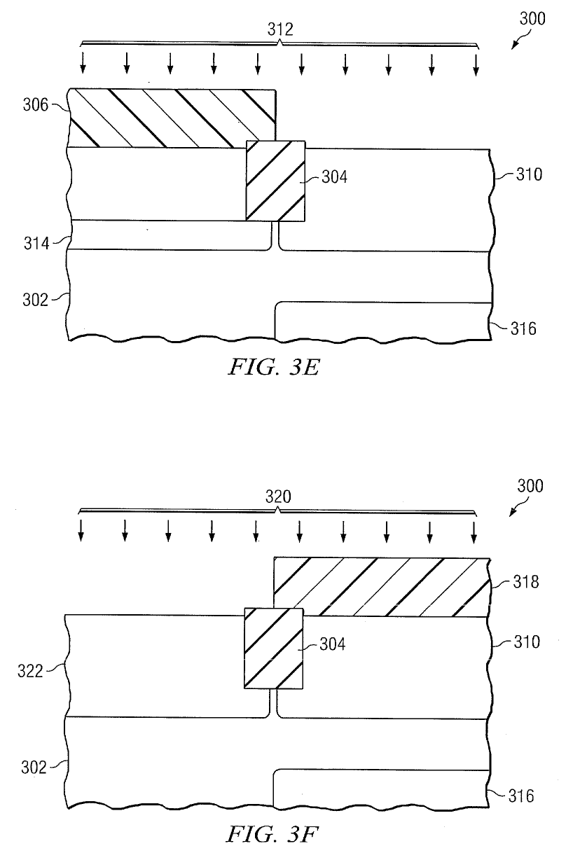

FIGS. 3A-3D are diagrams illustrating an exemplary method for forming self-aligned and tightly spaced well regions according to embodiments of the present disclosure. According to embodiments of the present disclosure, the well regions are formed by utilizing single mask layer during ion implantation for both well regions. FIG. 3A shows a partially completed semiconductor device 300. As illustrated, device 300 includes a substrate 302 including an isolation feature 304. One skilled in the art will realize that semiconductor device 300 is exemplary and can include other semiconductor device features.

Substrate 302 can be formed from any suitable semiconductor material, such as silicon. For example, substrate 302 can be a silicon wafer, a silicon wafer with previously embedded devices, an epitaxial layer grown on a wafer, a semiconductor on insulation (“SOI”) system, or other suitable substrates having any suitable crystal orientation.

Substrate 302 can be doped to be either N-type or P-type depending of the type of semiconductor device 300. For the purpose of this exemplary embodiment, substrate 302 will be described as being P-type. One skilled in the art will realize that substrate 302 can be N-type.

Isolation feature 304 can be formed of any suitable isolation structure such as shallow trench isolation (STI) regions, field oxide regions (LOCOS), and the like. STI 304 can be formed of any well-known isolation material utilizing any well-known processing technique. For example, a trench can be formed in substrate 302. The trench can be filled with a dielectric material, such silicon dioxide, and excess material can be removed by a process, such as chemical mechanical polishing (CMP), to form isolation feature 304.

As illustrated in FIG. 3A, a mask layer 306 is formed over a portion of substrate 302. Mask layer 306 can be formed using any suitable technique available in semiconductor processing, such as deposition, growth, combination thereof, and the like. Portions of mask layer 306 can be removed using any suitable technique available in semiconductor processing, such as etching. For example, mask layer 306 can be formed by depositing a mask layer over the entire substrate 306 and removing a portion to expose a region of substrate 302 where the N-type well region will be formed.

Mask layer 306 can be formed of any suitable material to block implantation of ions during the formation of the N-type well region. For example, mask layer 306 can be a nitride layer, oxide layer, combination thereof, and the like. Mask layer 306 can be formed to a suitable thickness to block implantations of ions during the formation of the N-type well region. Additionally, mask layer 306 can be formed to a suitable thickness to allow implantation of ions during formation of the P-type well region under mask layer 306. For example, resist mask 306 can be formed to a thickness ranging from approximately 2000 Å to approximately 3500 Å.

As illustrated in FIG. 3B, after formation of mask layer 306, an ion implantation 308 is performed to form N-type well region 310. For example, arsenic, P, antimony, or other suitable N-type dopants can be implanted in substrate 302 during ion implantation 308 to form N-type well region 310.

Ion implantation 308 can use a suitable energy, concentration, and implantation time to form N-type well region 310 in substrate 302 including a portion formed under isolation feature 304. For example, one or more implantations of P can be performed with the implants ranging from approximately 1e12 atoms/cm² to approximately 1e14 atoms/cm² at implantation energies ranging from approximately 20 KeV to approximately 700 KeV. For example, multiple P implants can be approximately 1e12 atoms/cm² at an implantation energy of approximately 50 KeV, approximately 4e12 atoms/cm² at an implantation energy of approximately 150 KeV, approximately 4e12 atoms/cm² at an implantation energy of approximately 320 KeV, and approximately 4e13 atoms/cm² at an implantation energy of approximately 675 KeV.

As illustrated in FIG. 3C, after ion implantation 308, an ion implantation 312 is performed to form P-type well region 314 under mask layer 306. For example, B, In, or other suitable P-type dopants can be implanted in substrate 302 during ion implantation 312 to form P-type well region 314.

Ion implantation 312 can use a suitable energy, concentration, and implantation time to form P-type well region 314 through mask layer 306 in substrate 302 including a portion formed under isolation feature 304. For example, if the second-type well region is a P-type well region one or more implantations of B can be performed with the implants ranging from approximately 1e12 atoms/cm² to approximately 1e14 atoms/cm² at implantation energies ranging from approximately 500 KeV to approximately 1500 KeV. For example, multiple B implants can be approximately 8e12 atoms/cm² at an implantation energy of approximately 550 KeV, approximately 3.5e13 atoms/cm² at an implantation energy of approximately 1000 KeV, approximately 2e12 atoms/cm² at an implantation energy of approximately 370 KeV, and approximately 7e12 atoms/cm² at an implantation energy of approximately 420 KeV.

After ion implantation 312, as illustrated in FIG. 3D, mask layer 306 is removed. Mask layer 306 can be removed utilizing any well-known technique, such as etching, available in semiconductor processing.

According to embodiments of the present disclosure, since only a single mask layer 306 is utilized, a P-type region 316 can be formed below N-type well region 310. Since ion implantation 312 utilizes an energy suitable to form P-type well region 314 through mask layer 306, P-type region 316 is formed below N-type well region 310 at a depth such that P-type region 316 does not affect the performance of N-type well region 310 and P-type well region 314. Additionally, as illustrated in FIG. 3D, since only a single mask layer is utilized during both ion implantation 308 and 312, N-type well region 310 and P-type well region 314 are self-aligned and tightly spaced.

As described above, the P-type well region can be formed utilizing both deep and shallow implants with the mask layer 306. Alternatively, mask layer 306 can be utilized with high energy implants to form the deep implants of P type well region 310, and a separate mask can be utilized with low energy implants to from shallow implants of P-type well region 314. FIGS. 3E and 3F are diagrams illustrating another exemplary method of forming the P-type well region consistent with embodiments of the present disclosure. In this exemplary embodiment, the method illustrated in FIGS. 3E and 3F would replace the method illustrated in FIG. 3C described above.

As illustrated in FIG. 3E, after ion implantation 308, an ion implantation 312 is performed to form deep implant region 314 of the P-type well region under mask layer 306. For example, B, In, or other suitable P-type dopants can be implanted in substrate 302 during ion implantation 312.

Ion implantation 312 can use a suitable energy, concentration, and implantation time to form deep implant region 314 of the P-type well region through mask layer 306 in substrate 302 including a portion formed under isolation feature 304. For example, one or more implantations of B can be performed with the implants ranging from approximately 1e12 atoms/cm² to approximately 1e14 atoms/cm² at implantation energies ranging from approximately 500 KeV to approximately 1500 KeV. For example, multiple B implants can be approximately 8e12 atoms/cm² at an implantation energy of approximately 550 KeV, and approximately 3.5e13 atoms/cm² at an implantation energy of approximately 1000 KeV.

As illustrated in FIG. 3F, after ion implantation 312, mask layer 306 is removed. Mask layer 306 can be removed utilizing any well-known technique, such as etching, available in semiconductor processing. Then, a separate mask layer 318 is formed over N-type well region 310. Mask layer 318 is formed so that the P-type well region is exposed and N-type well region 310 is covered. Mask layer 318 can be formed of any suitable material to block implantation of ions during the formation of the shallow implant of the P-type well region. For example, mask layer 318 can be a photo resist and the like. Mask layer 318 can be formed to a suitable thickness to block implantations of ions during the formation of the shallow region of the P-type well region.

After forming mask layer 318, an ion implantation 320 is performed to form shallow implants in order to complete P-type well region 322. For example, B, In, or other suitable P-type dopants can be implanted in substrate 302 during ion implantation 320.

Ion implantation 320 can use a suitable energy, concentration, and implantation time to form the shallow implants of P-type well region 322. For example, one or more implantations of B can be performed with the implants ranging from approximately 1e12 atoms/cm² to approximately 1e14 atoms/cm² at implantation energies ranging from approximately 5 KeV to approximately 150 KeV. For example, multiple B implants can be approximately 2e12 atoms/cm² at an implantation energy of approximately 20 KeV and approximately 7e12 atoms/cm² at an implantation energy of approximately 70 KeV.

After ion implantation 320, mask layer 318 is removed. Mask layer 318 can be removed utilizing any well-known technique, such as etching, available in semiconductor processing.

In the above exemplary embodiments described above, N-type well region 310 was formed first and P-type well region 316 was formed below mask layer 306. In another embodiment of the present disclosure, the N-type well region may be formed below mask layer 306. In this exemplary embodiment, the process steps would be similar with ion implantation 308 utilizing P-type dopants and ion implantation 312 utilizing N-type dopants.

FIGS. 3A-3F illustrate a single N-type well region and P-type well region being formed in device 300 according to embodiments of the present disclosure. One skilled in the art will realize that substrate 302 illustrated above is a partial view of device 300 and realize that can include additional well regions. FIG. 4 is a diagram illustrating a device 400 which may include multiple N-type well regions and multiple P-type well regions. As illustrated, device 400 includes a substrate 400 including multiple isolation features 404.

According to embodiments of the present disclosure, multiple mask layers 406 can be formed over substrate 402. Mask layer 406 can be formed by forming a mask layer over the entire substrate 402 and removing portions to expose a region of substrate 402 where the multiple N-type wells regions will be formed. Subsequently, multiple N-type well regions and multiple P-type well regions can be formed utilizing the process described above in FIG. 3B-3B. Additionally, multiple N-type well regions and multiple P-type well regions can be formed utilizing the process in which the N-type well regions are formed under mask layer 406 as described above.

Other embodiments of the present teaching will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of fabricating a semiconductor device, comprising:
forming a mask layer over a portion of a substrate;
implanting ions in the substrate to form a first-type well region in an un-masked portion of the substrate; and
implanting ions in the substrate to form a second-type well region under the mask layer, wherein the ions are implanted at an energy to form the second-type well region through the mask layer.

2. The method of claim 1, wherein implanting ions in the substrate to form the second-type well region comprises:
implanting ions to from deep regions of the second-type well region;
removing the mask layer;
forming a second mask layer over the first-type well region; and
implanting ions to from shallow regions of the second-type well region.

3. The method of claim 1, wherein forming the mask layer comprises:
depositing the mask layer over the substrate; and
etching the mask layer to remove part of the mask layer, wherein the mask layer remains over the portion of the substrate.

4. The method of claim 1, wherein the mask layer is a nitride layer.

5. The method of claim 1, wherein the mask layer is formed to a thickness ranging from approximately 2000 Å to approximately 3500 Å.

6. The method of claim 1, wherein the substrate includes an isolation region formed between the first-type well region and the second-type well region.

7. The method of claim 6, wherein a portion of the first-type well region and a portion of the second-type well region are formed below the isolation region.

8. The method of claim 1, wherein the substrate is a P-type substrate and wherein the first-type well region is an N-type well region and the second-type well region is a P-type well region.

9. The method of claim 1, wherein the substrate is a P-type substrate and wherein the first-type well region is a P-type well region and the second-type region is an N-type well region.

10. The method of claim 1, wherein the substrate is an N-type substrate and wherein the first-type well region is an N-type well region and the second-type well region is a P-type well region.

11. The method of claim 1, wherein the substrate is an N-type substrate and wherein the first-type well region is a P-type well region and the second-type region is an N-type well region.

12. The method of claim 1, wherein implanting ions to form the first-type well region comprises implanting phosphorous, P, ions ranging from approximately 1e12 atoms/cm² to approximately 1e14 atoms/cm² at implantation energies ranging from approximately 20 KeV to approximately 700 KeV.

13. The method of claim 1, wherein implanting ions to from the second-type well region comprises implanting boron, B, ions ranging from approximately. 1e12 atoms/cm² to approximately 1e14 atoms/cm² at implantation energies ranging from approximately 500 KeV to approximately 1500 KeV.

14. A method of fabricating a semiconductor device, comprising:
forming a mask layer over a portion of a substrate;
implanting ions in the substrate to form a plurality of first-type well regions in an un-masked portion of the substrate; and
implanting ions in the substrate to form a plurality of second-type well regions under the mask layer, wherein the ions are implanted at an energy to form the plurality of second-type well regions through the mask layer.

15. The method of claim 14, wherein implanting ions in the substrate to form the plurality of second-type well region comprises:
implanting ions to from deep regions of the plurality of second-type well regions;
removing the mask layer;
forming a second mask layer over the plurality of first-type well regions; and
implanting ions to from shallow regions of the plurality of second-type well regions.

16. The method of claim 14, wherein forming the mask layer comprises:
depositing the mask layer over the substrate; and
etching the mask layer to remove parts of the mask layer, wherein the mask layer remains over portions of the substrate.

17. The method of claim 14, wherein the mask layer is a nitride layer.

18. The method of claim 14, wherein the mask layer is formed to a thickness ranging from approximately 2000 Å to approximately 3500 Å.

19. The method of claim 14, wherein implanting ions to form the plurality of first-type well regions comprises implanting phosphorous, P, ions ranging from approximately 1e12 atoms/cm² to approximately 1e14 atoms/cm² at implantation energies ranging from approximately 20 KeV to approximately 700 KeV.

20. The method of claim 14, wherein implanting ions to form the plurality of second-type well regions comprises implanting boron, B, ions ranging from approximately 1e12 atoms/cm² to approximately 1e14 atoms/cm² at implantation energies ranging from approximately 500 KeV to approximately 1500 KeV.
